(19) United States
(12) Patent Application Publication
(10) Pub. No.: US 2024/0123391 A1
(43) Pub. Date: Apr. 18, 2024

(54) TUNGSTEN PRECURSORS AND RELATED METHODS

(71) Applicant: ENTEGRIS, INC., Billerica, MA (US)

(72) Inventors: Robert Wright, JR., Newtown, CT (US); Bryan Hendrix, Danbury, CT (US); Loren Press, Burnet, TX (US); Benjamin Garrett, Leander, TX (US)

(21) Appl. No.: 18/376,471

(22) Filed: Oct. 4, 2023

Related U.S. Application Data
(60) Provisional application No. 63/413,507, filed on Oct. 5, 2022.

(51) Int. Cl. B01D 53/00; C01G 41/04

(52) U.S. Cl. CPC B01D 53/002; C01G 41/04

(57) ABSTRACT

Tungsten precursors with high purity and methods for purifying tungsten precursors are provided. The method for purifying a precursor may comprise at least one of the following steps: obtaining a source vessel containing WCl₄, WOCl₄, and one of WCl₅ or WCl₆; separating the WCl₅ or the WCl₆ from at least a first portion of the WOCl₄; separating the WCl₅ or the WCl₆ from at least a second portion of the WOCl₄; recovering a precursor in a collection vessel; or any combination thereof.

### FIELD

The present disclosure relates to the field of tungsten precursors and related methods, including, for example and without limitation, methods for purifying and methods for validating impurity levels.

### BACKGROUND

The presence of impurities in precursors used for semiconductor fabrication results in defects and undesired process variability. Specifically, for solid precursors, separate crystals of an impurity can incorporate into the vapor stream at levels much higher than dissolved impurities at the same impurity level. With the high sensitivity of the vapor content to impurity levels, current analytical techniques for measuring impurity level are not capable of detecting sufficiently low impurity levels.

### SUMMARY

Some embodiments relate to a method for purifying a tungsten precursor. The method for purifying the tungsten precursor may comprise one or more of the following steps, which may be performed in any order and in any combination. In some embodiments, the method comprises obtaining a source vessel containing WCl₄, WOCl₄, and one of WCl₅ or WCl₆. In some embodiments, the method comprises separating the WCl₅ or the WCl₆ from a first portion of the WOCl₄, wherein the separating comprises: applying a first condition to the source vessel, so as to produce a first WOCl₄ vapor; and removing at least a portion of the first WOCl₄ vapor from the source vessel. In some embodiments, the method comprises separating the WCl₅ or the WCl₆ from a second portion of the WOCl₄, wherein the separating comprises: applying a second condition to the source vessel, so as to produce a WCl₅ vapor comprising (e.g., any remaining) WOCl₄ or a WCl₆ vapor comprising (e.g., any remaining) WOCl₄; flowing the WCl₅ vapor or the WCl₆ vapor to a collection vessel; applying a third condition to the collection vessel, so as to produce a WCl₅ condensate or a WCl₆ condensate, and a second WOCl₄ vapor; and removing at least a portion of the second WOCl₄ vapor from the collection vessel. In some embodiments, the method comprises recovering a precursor in a collection vessel. In some embodiments, the method comprises validating a low WOCl₄ content of the precursor recovered in the collection vessel.

Some embodiments relate to a method for validating a low impurity content. In some embodiments, the method comprises obtaining a collection vessel containing a WCl₅ precursor or a WCl₆ precursor. In some embodiments, the method comprises applying a condition to the collection vessel containing the WCl₅ precursor or the WCl₆ precursor. In some embodiments, the method comprises measuring at least one of a total pressure within the collection vessel, a rate of change of total pressure within the collection vessel, or any combination thereof. In some embodiments, the method comprises comparing the total pressure or the rate of change of total pressure to a reference value so as to validate or not validate a low WOCl₄ content. In some embodiments, the method comprises removing the WOCl₄ from the collection vessel when the low WOCl₄ content is not validated.

Some embodiments relate to a precursor vessel. In some embodiments, the precursor vessel comprises a precursor. In some embodiments, the precursor comprises WCl₅. In some embodiments, the WCl₅ has, when the precursor vessel is maintained at a temperature of 70° C. (343.15 K) to 240° C. (513.15 K), a vapor pressure of less than 1.3 times a calculated vapor pressure of WCl₅ determined according to the formula:

Log P(Torr)=11.119+−4634/T(K)

Some embodiments relate to a precursor vessel. In some embodiments, the precursor vessel comprises a precursor. In some embodiments, the precursor comprises WCl₆. In some embodiments, the WCl₆ has, when the precursor vessel is maintained at a temperature of 70° C. (343.15 K) to 240° C. (513.15 K), a vapor pressure of less than 1.3 times a calculated vapor pressure of WCl₆ determined according to the formula:

Log P(Torr)=11.429+−4894/T(K)

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for purifying a tungsten precursor, according to some embodiments.

FIG. 2 is a flowchart of a method for separating a tungsten precursor from an impurity, according to some embodiments.

FIG. 3 is a flowchart of a method for separating a tungsten precursor from an impurity, according to some embodiments.

FIG. 4 is a flowchart of a method for validating a low impurity content of a tungsten precursor, according to some embodiments.

FIG. 5 is a flowchart of a method for measuring a low impurity content of a tungsten precursor, according to some embodiments.

FIG. 6 is a flowchart of a method for measuring a low impurity content of a tungsten precursor, according to some embodiments.

FIG. 7 is a graphical view of a vapor pressure curve, according to some embodiments.

FIG. 8 is a graphical view of vapor pressure versus pumping time, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to a method for purifying a tungsten precursor. Various embodiments of the method for purifying the tungsten precursor are provided herein. It will be appreciated that any combination of steps, in any order, may be performed in the method for purifying the tungsten precursor, without departing from the scope of this disclosure. Accordingly, that various methods and the steps of those methods are depicted in different figures shall not be limiting, as any combination of steps in any of the figures disclosed herein, in any combination, may be performed, without departing from the scope of this disclosure.

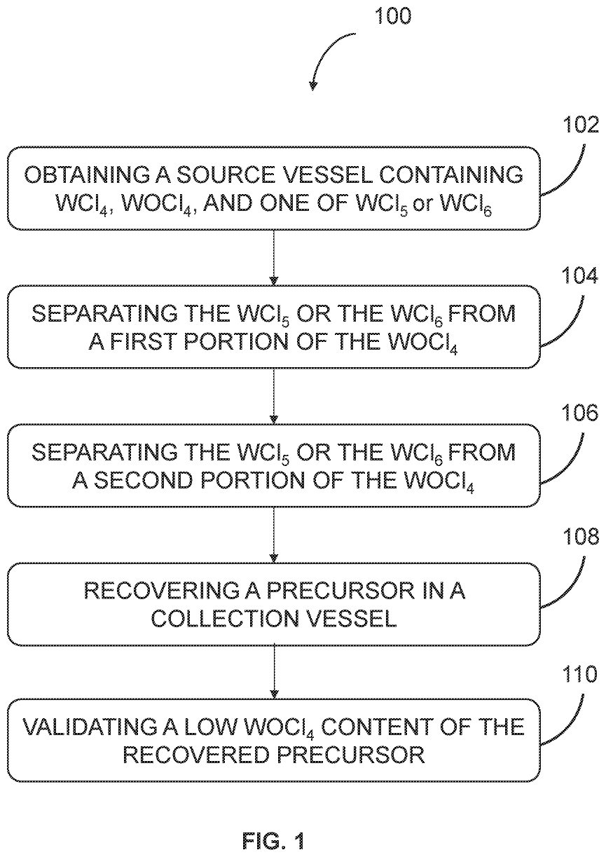

FIG. 1 is a flowchart of a method 100 for purifying a tungsten precursor, according to some embodiments. In some embodiments, the method 100 relates to a method for purifying WCl₅. As shown in FIG. 1, in some embodiments, the method 100 for purifying a tungsten precursor may comprise at least one of the following steps: a step 102 of obtaining a source vessel containing WCl₄, WOCl₄, and one of WCl₅ or WCl₆; a step 104 of separating the WCl₅ or the WCl₆ from a first portion of the WOCl₄; a step 106 of separating the WCl₅ or the WCl₆ from a second portion of the WOCl₄; a step 108 of recovering a precursor in a collection vessel; a step 110 of validating a low WOCl₄ content of the recovered precursor; or any combination thereof.

At step 102, in some embodiments, a source vessel containing at least one of WCl₄, WOCl₄, one of WCl₅ or WCl₆, or any combination thereof, is obtained. The WCl₅ or the WCl₆ may be present in the source vessel in the form of at least one of a solid, a gas/vapor, or any combination thereof. For example, in some embodiments, the WCl₅ or the WCl₆ is present as a solid and as a vapor. In some embodiments, the solid phase of the WCl₅ or the WCl₆ is amorphous or crystalline. In some embodiments, the WCl₅ or the WCl₆ is present in the source vessel as an isolated crystal. The WCl₄ may be present in the source vessel in the form of at least one of a solid, a gas/vapor, or any combination thereof. For example, in some embodiments, the WCl₄ may be present as a solid and as a vapor, with substantially less WCl₄ vapor than the WCl₅ vapor or the WCl₆ vapor. In some embodiments, the WCl₄ is present in the source vessel as an isolated crystal. In some embodiments, the WCl₄ is present within the solid phase of the WCl₅ or the WCl₆. For example, in some embodiments, the WCl₄ is dissolved in the crystal lattice of the WCl₅ or the WCl₆. The WOCl₄ may be present in the source vessel in the form of at least one of a solid, a gas/vapor, or any combination thereof. For example, in some embodiments, the WOCl₄ may be present as a solid and as a vapor. The solid phase of the WOCl₄ may be amorphous or crystalline. In some embodiments, the WOCl₄ is present in the source vessel as an isolated crystal. In some embodiments, the WOCl₄ is present within the solid phase of the WCl₅. For example, in some embodiments, the WOCl₄ is dissolved in the crystal lattice of the WCl₅ or the WCl₆. In some embodiments, the WOCl₄ is present within the solid phase of the WCl₄. The solid phase of the WCl₄ may be amorphous or crystalline. For example, in some embodiments, the WOCl₄ is dissolved in the crystal lattice of the WCl₄.

The source vessel may be configured to control temperature. The temperature of the source vessel may be controlled in any suitable manner. In some embodiments, a thermal jacket for heating and/or cooling is employed around the source vessel. In some embodiments, a ribbon heater is wound around the source vessel. In some embodiments, a block heater having a shape covering at least a major portion of the external surface of the source vessel is employed to heat the source vessel. In some embodiments, a resistive heater is employed to heat the source vessel. In some embodiments, a lamp heater is employed to heat the source vessel. In some embodiments, a heat transfer fluid at elevated temperature may be contacted with the exterior surface of the source vessel, to effect heating and/or cooling thereof. In some embodiments, the heating is conducted by infrared or other radiant energy being impinged on the source vessel. In some embodiments, the collection vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The source vessel may be configured to control pressure. The pressure of the source vessel may be controlled in any suitable manner. In some embodiments, a gas inlet line is fluidly coupled to the source vessel. The gas inlet line may be configured to supply a pressurizing gas from a pressurizing gas source to the source vessel. Control of the pressurizing gas into the source vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the source vessel. The vacuum line may be configured to apply a vacuum to the source vessel. In some embodiments, the pumping speed is controlled by butterfly valves. It will be appreciated that other mechanisms for controlling the pressure of the source vessel may be employed herein without departing from the scope of this disclosure.

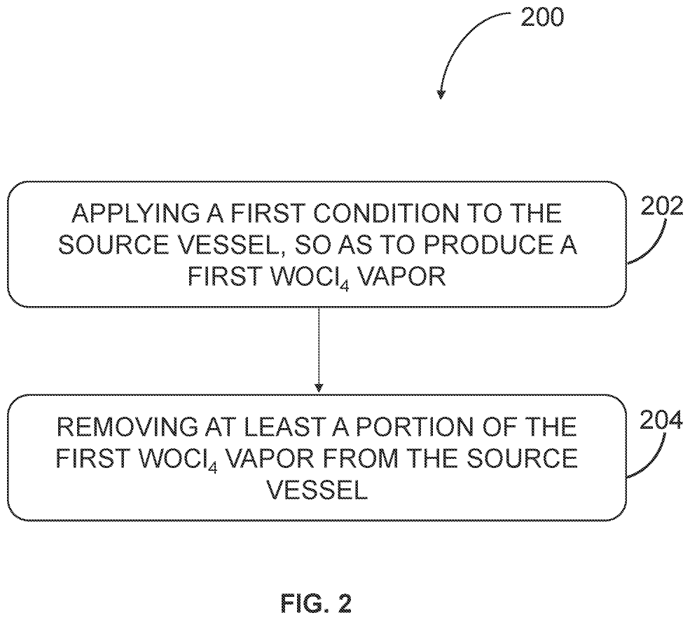

At step 104, in some embodiments, the WCl₅ is separated from the first portion of the WOCl₄. As disclosed herein (e.g., in FIG. 2), in some embodiments, the WCl₅ or the WCl₆ may be separated from the first portion of the WOCl₄ by applying a first condition (e.g., at least one of a temperature, a pressure, an inert gas flow, a vacuum, or any combination thereof) to the source vessel, so as to produce a first WOCl₄ vapor. In some embodiments, the WCl₅ or the WCl₆ may be separated from the first portion of the WOCl₄ by removing at least a portion of the first WOCl₄ from the source vessel. In some embodiments, the first condition is a condition under which a total pressure of the source vessel is below a true vapor pressure of WOCl₄ for a given first temperature. In some embodiments, the first condition is a condition under which a total pressure of the source vessel is above a true vapor pressure of WCl₅ for a given first temperature. In some embodiments, when applying the first condition, the first WOCl₄ vapor comprises a greater volume of WOCl₄ than WCl₅.

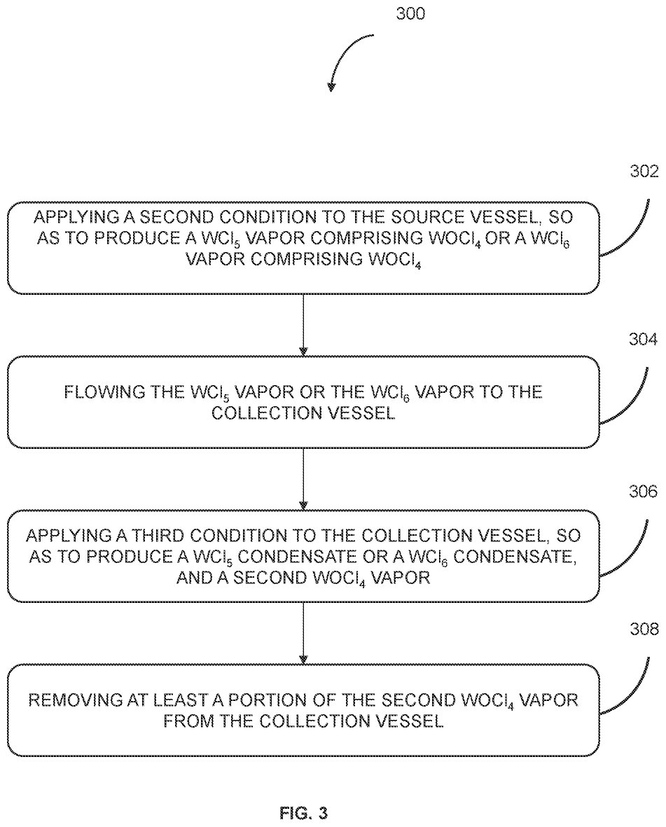

At step 106, in some embodiments, the WCl₅ or the WCl₆ is separated from the second portion of the WOCl₄ and the WCl₄. This step may also involve or result in separating the WCl₅ or the WCl₆ from the WOCl₄. As disclosed herein (e.g., in FIG. 3), in some embodiments, the WCl₅ or the WCl₆ may be separated from the second portion of the WOCl₄— and, in some embodiments, the WCl₄— by applying a second condition (e.g., at least one of a temperature, a pressure, an inert gas flow, a vacuum, or any combination thereof) to the source vessel, so as to produce a WCl₅ vapor comprising WOCl₄ or a WCl₆ vapor comprising WOCl₄; flowing the WCl₅ vapor or the WCl₆ vapor to a collection vessel; applying a third condition (e.g., at least one of a temperature, a pressure, an inert gas flow, a vacuum, or any combination thereof) to the collection vessel, so as to produce a WCl₅ condensate or a WCl₆ condensate, and a second WOCl₄ vapor; and removing at least a portion of the second WOCl₄ vapor from the collection vessel.

In some embodiments, the second condition is a condition under which a total pressure of the source vessel is below a true vapor pressure of the WCl₅ or the WCl₆ for a given second temperature. In some embodiments, the second condition is a condition under which a total pressure of the source vessel is above a true vapor pressure of the WCl₄ for a given second temperature. In some embodiments, when applying the second condition, the WCl₅ vapor or the WCl₆ vapor comprises a greater volume of the WCl₅ or the WCl₆, than the WCl₄. In some embodiments, when applying the second condition, the WCl₅ vapor or the WCl₆ vapor comprises a greater volume of the WOCl₄ than the WCl₄. In some embodiments, the third condition is a condition under which a greater volume of the WCl₅ or the WCl₆ condenses than the WOCl₄. In some embodiments, when applying the third condition, the WCl₅ condensate comprises a greater mole fraction of WCl₅ than WOCl₄. In some embodiments, when applying the third condition, the WCl₆ condensate comprises a greater mole fraction of WCl₆ than WOCl₄.

The collection vessel may be configured to control temperature. The temperature of the collection vessel may be controlled in any suitable manner. In some embodiments, a thermal jacket for heating and/or cooling is employed around the collection vessel. In some embodiments, a ribbon heater is wound around the collection vessel. In some embodiments, a block heater having a shape covering at least a major portion of the external surface of the collection vessel is employed to heat the collection vessel. In some embodiments, a resistive heater is employed to heat the collection vessel. In some embodiments, a lamp heater is employed to heat the collection vessel. In some embodiments, a heat transfer fluid at elevated temperature may be contacted with the exterior surface of the collection vessel, to effect heating and/or cooling thereof. In some embodiments, the heating is conducted by infrared or other radiant energy being impinged on the collection vessel. In some embodiments, the collection vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The collection vessel may be configured to control pressure. The pressure of the collection vessel may be controlled in any suitable manner. In some embodiments, a gas inlet line is fluidly coupled to the collection vessel. The gas inlet line may be configured to supply a pressurizing gas from a pressurizing gas source to the collection vessel. Control of the pressurizing gas into the collection vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the collection vessel. The vacuum line may be configured to apply a vacuum to the collection vessel. In some embodiments, the pumping speed is controlled by butterfly valves. It will be appreciated that other mechanisms for controlling the pressure of the source vessel may be employed herein without departing from the scope of this disclosure.

At step 108, in some embodiments, the precursor is recovered in the collection vessel. In some embodiments, the precursor comprises WCl₅ or WCl₆. In some embodiments, the precursor comprises WCl₅ or WCl₆ and a low WOCl₄ content. In some embodiments, the collection vessel comprising the WCl₅ or the WCl₆ has, when the precursor vessel is maintained at a temperature of 70° C. (343.15 K) to 240° C. (513.15 K), a vapor pressure of less than 1.1 times a calculated vapor pressure of WCl₅ determined according to the formula:

$$\\ Log P ( Torr ) = 11.119 + \frac{- 4634}{T ( K )}$$

In some embodiments, the WCl₅ or the WCl₆ maintains the vapor pressure for a duration up to 72 hours. In some embodiments, the WCl₅ or the WCl₆ maintains the vapor pressure for a duration of 5 minutes to 72 hours.

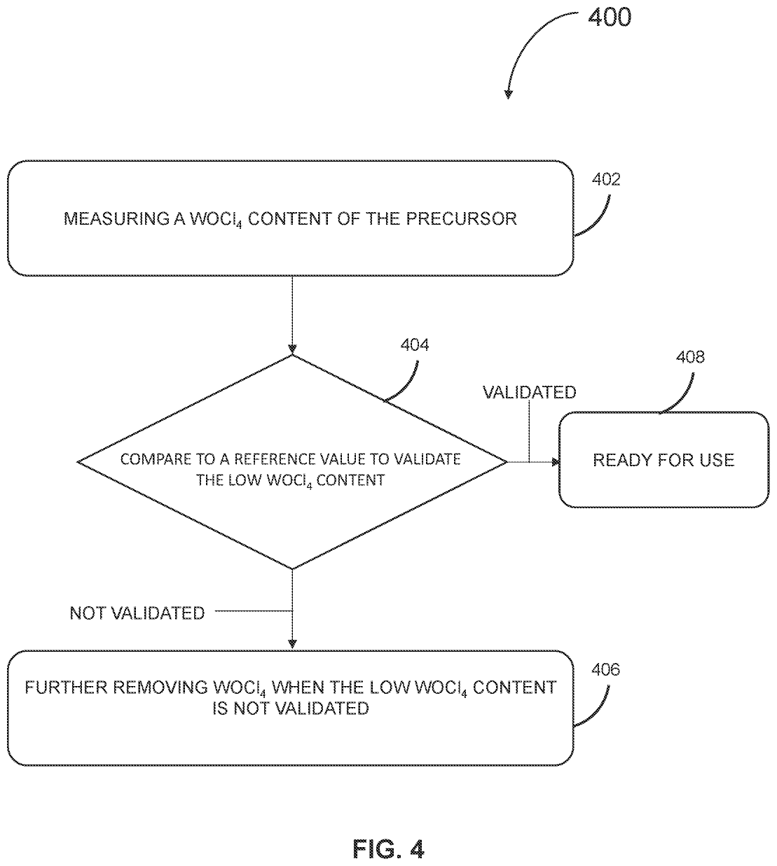

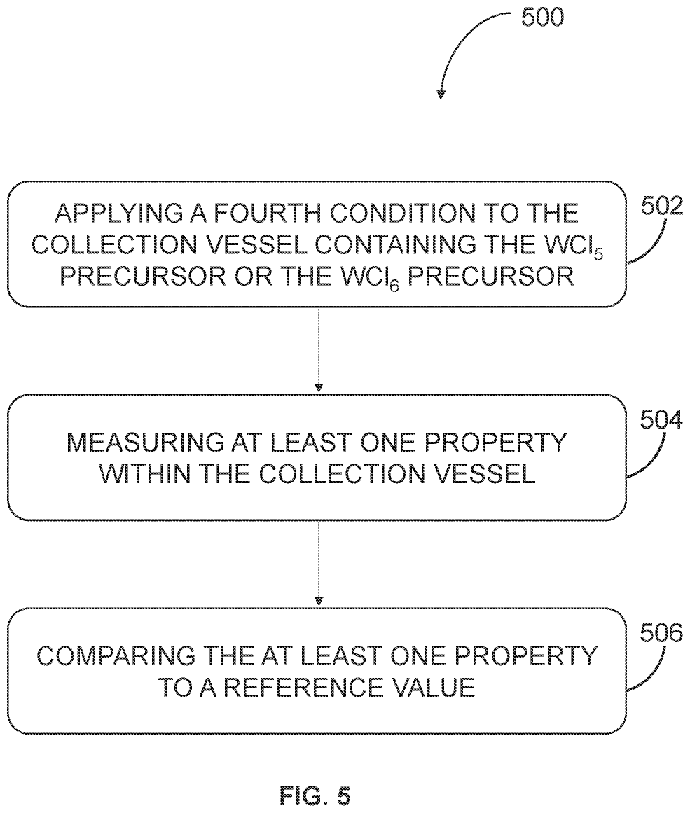

At step 110, in some embodiments, the low WOCl₄ content of the recovered precursor is validated. As disclosed herein (e.g., FIG. 4 and FIG. 5), in some embodiments, the low WOCl₄ content of the recovered precursor may be validated by measuring a WOCl₄ content of the precursor, so as to validate or not validate the low WOCl₄ content of the precursor and, when the low WOCl₄ content of the precursor is not validated, repeating at least one of step 104, step 106, or any combination thereof, so as to remove the WOCl₄. In some embodiments, the WOCl₄ content of the precursor is measured by applying a fourth condition to the collection vessel containing the precursor; measuring a total pressure within the collection vessel; and comparing the total pressure to a reference value. In some embodiments, when the total pressure is within a percentage of the reference value (e.g., within 0.01% to 20% of a true vapor pressure of the WCl₅ or the WCl₆ at conditions), the low WOCl₄ content of the precursor is validated. In some embodiments, when the total pressure is not within the percentage of the reference value (e.g., within 0.01% to 20% of a true vapor pressure of the WCl₅ or the WCl₆ at conditions), the low WOCl₄ content of the precursor is not validated. In some embodiments, the fourth condition is selected to stabilize the collection vessel at a reference temperature; an inlet gas flow to the collection vessel is stopped; a short vacuum pump removes inert gas from the vapor phase in the collection vessel; the collection vessel is isolated from the vacuum pump; and then the pressure in the collection vessel is monitored or measured over time. In some embodiments, the WOCl₄ content of the precursor is measured by applying a fourth condition to the collection vessel containing the precursor; measuring a rate of change of total pressure within the collection vessel; and comparing the rate of change of total pressure to a reference value. In some embodiments, when the rate of change of total pressure is greater than the reference value, the low WOCl₄ content of the precursor is not validated. In some embodiments, when the rate of change of total pressure is equal to or less than the reference value, the low WOCl₄ content of the precursor is validated. In some embodiments, when the rate of change of total pressure is 5% or less, 4% or less, 3% or less, 2% or less, or 1% or less, the low WOCl₄ content of the precursor is validated. In some embodiments, the WCl₆ is an impurity in the WCl₅ (e.g., is present in the WCl₅ condensate). In some embodiments, the WCl₅ is an impurity in the WCl₆ (e.g., is present in the WCl₆ condensate). In some embodiments, the total pressure is equal to the sum of the WCl₅ vapor pressure and the WCl₆ vapor pressure (e.g., total pressure=0.6 T (for WCl₅)+0.3 T (for WCl₆) 0.9 T).

FIG. 2 is a flowchart of a method 200 for separating a tungsten precursor from an impurity, according to some embodiments. As shown in FIG. 2, in some embodiments, the method 200 for separating a tungsten precursor from an impurity may comprise at least one of the following steps: a step 202 of applying a first condition to the source vessel, so as to produce a first WOCl₄ vapor; a step 204 of removing at least a portion of the first WOCl₄ vapor from the source vessel; or any combination thereof. In some embodiments, the method 200 relates to separating the WCl₅ from the first portion of the WOCl₄ as described above.

At step 202, in some embodiments, the first condition is applied to the source vessel, so as to produce the first WOCl₄ vapor. In some embodiments, the first condition includes a first temperature of the source vessel. In some embodiments, the first temperature of the source vessel is a temperature in a range of 60° C. to 170° C., or any range or subrange between 60° C. to 170° C. In some embodiments, the first temperature of source vessel is a temperature in a range of 60° C. to 160° C., 60° C. to 150° C., 60° C. to 140° C., 60° C. to 130° C., 60° C. to 120° C., 60° C. to 110° C., 60° C. to 100° C., 60° C. to 90° C., 60° C. to 80° C., 60° C. to 70° C., 70° C. to 170° C., 80° C. to 170° C., 90° C. to 170° C., 100° C. to 170° C., 110° C. to 170° C., 120° C. to 170° C., 130° C. to 170° C., 140° C. to 170° C., 150° C. to 170° C., 160° C. to 170° C., 100° C. to 160° C., 120° C. to 160° C., 140° C. to 160° C., 120° C. to 150° C., 120° C. to 140° C., or 110° C. to 150° C.

In some embodiments, the first condition includes a first pressure of the source vessel. In some embodiments, the first pressure of the source vessel is a pressure in a range of 0.01 Torr to 100 Torr, or any range or subrange therebetween. In some embodiments, the first pressure of the source vessel is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 1 Torr, 0.01 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr.

In some embodiments, the first condition is a condition under which a total pressure of the source vessel is below a true vapor pressure of WOCl₄ for a given first temperature. In some embodiments, the first condition is a condition under which a total pressure of the source vessel is above a true vapor pressure of WCl₅ for a given first temperature. In some embodiments, the first condition is a condition such that the WOCl₄ vaporizes, while minimizing the amount of WCl₅ or WCl₆ that is vaporized. In some embodiments, the first condition is a condition such that the WCl₅ or the WCl₆ is not vaporized. In some embodiments, the first condition is a condition such that isolated crystals of WOCl₄ are vaporized. In some embodiments, the first condition is a condition such that the WOCl₄, which is present in the crystal lattice of WCl₅ or WCl₆, is not vaporized or not appreciably vaporized. Once vaporized, the first WOCl₄ vapor may be removed from the source vessel, so as to separate the WOCl₄ from the WCl₅ or the WCl₆.

The first WOCl₄ vapor may comprise a greater volume of WOCl₄ than WCl₅ or WCl₆. In some embodiments, the first WOCl₄ vapor comprises less than 10%, less than 9%, less than 8%, less than 7%, less than 6%, less than 5%, less than 4%, less than 3%, less than 2%, less than 1%, less than 0.1%, less than 0.01% by volume of the WCl₅ based on a total volume of the first WOCl₄ vapor. In some embodiments, the first WOCl₄ vapor comprises 0.01% to 10%, 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.1%, 0.1% to 10%, 1% to 10%, 2% to 10%, 3% to 10%, 4% to 10%, 5% to 10%, 6% to 10%, 7% to 10%, 8% to 10%, or 9% to 10% by volume of the WCl₅ or the WCl₆ based on the total volume of the first WOCl₄ vapor.

At step 204, in some embodiments, at least a portion of the first WOCl₄ vapor is removed from the source vessel. The first WOCl₄ vapor may be removed via an outlet of the source vessel. The outlet may be fluidly coupled to a gas discharge line, a vacuum line, or other similar line suitable for removing the first WOCl₄ vapor from the source vessel.

FIG. 3 is a flowchart of a method 300 for separating a tungsten precursor from an impurity, according to some embodiments. As shown in FIG. 3, in some embodiments, the method 300 for separating a tungsten precursor from an impurity may comprise at least one of the following steps: a step 302 of applying a second condition to the source vessel, so as to produce a WCl₅ vapor or a WCl₆ vapor comprising WOCl₄; a step 304 of flowing the WCl₅ vapor or the WCl₆ vapor to the collection vessel; a step 306 of applying a third condition to the collection vessel, so as to produce a WCl₅ condensate or a WCl₆ condensate, and a second WOCl₄ vapor; a step 308 of removing at least a portion of the second WOCl₄ vapor from the collection vessel; or any combination thereof. In some embodiments, the method 300 relates to separating the WCl₅ or the WCl₆ from the second portion of the WOCl₄ as described above. The method 300 for separating the WCl₅ or the WCl₆ from the second portion of the WOCl₄ may also separate the WCl₅ or the WCl₆ from the WCl₄.

At step 302, in some embodiments, the second condition is applied to the source vessel, so as to produce the WCl₅ vapor or the WCl₆ vapor comprising the WOCl₄. In some embodiments, the second condition includes a second temperature of the source vessel. In some embodiments, the second temperature of the source vessel is a temperature in a range of 60° C. to 170° C., or any range or subrange between 60° C. to 170° C. In some embodiments, the second temperature of source vessel is a temperature in a range of 60° C. to 160° C., 60° C. to 150° C., 60° C. to 140° C., 60° C. to 130° C., 60° C. to 120° C., 60° C. to 110° C., 60° C. to 100° C., 60° C. to 90° C., 60° C. to 80° C., 60° C. to 70° C., 70° C. to 170° C., 80° C. to 170° C., 90° C. to 170° C., 100° C. to 170° C., 110° C. to 170° C., 120° C. to 170° C., 130° C. to 170° C., 140° C. to 170° C., 150° C. to 170° C., 160° C. to 170° C., 100° C. to 160° C., 120° C. to 160° C., 140° C. to 160° C., 120° C. to 150° C., 120° C. to 140° C., or 110° C. to 150° C. In some embodiments, the second temperature of the source vessel is greater than the first temperature of the source vessel. In some embodiments, the second temperature of the source vessel is less than the first temperature of the source vessel.

In some embodiments, the second condition includes a second pressure of the source vessel. In some embodiments, the second pressure of the source vessel is a pressure in a range of 0.01 Torr to 100 Torr, or any range or subrange therebetween. In some embodiments, the second pressure of the source vessel is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 1 Torr, 0.01 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr. In some embodiments, the second pressure of the source vessel is less than a first pressure of the source vessel. In some embodiments, the second pressure of the source vessel is greater than a first pressure of the source vessel.

In some embodiments, the second condition is a condition under which a total pressure of the source vessel is below a true vapor pressure of WCl₅ or WCl₆ for a given second temperature. In some embodiments, the second condition is a condition under which a total pressure of the source vessel is above a true vapor pressure of WCl₄ for a given second temperature. In some embodiments, the second condition is a condition such that the WCl₅ or the WCl₆ present in the source vessel as isolated crystals is vaporized. In some embodiments, the second condition is a condition such that the WCl₅ or the WCl₆ vaporizes, while minimizing the amount of WCl₄ that is vaporized. In some embodiments, the second condition is a condition such that the WCl₄ is not vaporized. In some embodiments, the second condition is a condition such that WOCl₄ present in the crystal lattice of the WCl₅ or the WCl₆ is vaporized. In some embodiments, the second condition is a condition such that the WOCl₄ present in the source vessel as isolated crystals is vaporized. In some embodiments, the WCl₅ vapor or the WCl₆ vapor comprises a greater volume of WCl₅ or WCl₆ than WOCl₄. In some embodiments, the WCl₅ vapor or the WCl₆ vapor comprises a greater volume of WOCl₄ than WCl₄. In some embodiments, the WCl₅ vapor or the WCl₆ vapor comprises a greater volume of WCl₅ or WCl₆ than WCl₄.

At step 304, in some embodiments, the WCl₅ vapor or the WCl₆ vapor is flowed to the collection vessel, so as to remove the WCl₅ vapor or the WCl₆ vapor from the WCl₄ contained within the source vessel. In some embodiments, the WCl₅ vapor or the WCl₆ vapor comprises the WOCl₄. In some embodiments, the WCl₅ vapor or the WCl₆ vapor comprises the WOCl₄ vapor.

The collection vessel may be configured to control temperature. The temperature of the collection vessel may be controlled in any suitable manner. In some embodiments, a thermal jacket for heating and/or cooling is employed around the collection vessel. In some embodiments, a ribbon heater is wound around the collection vessel. In some embodiments, a block heater having a shape covering at least a major portion of the external surface of the collection vessel is employed to heat the collection vessel. In some embodiments, a resistive heater is employed to heat the collection vessel. In some embodiments, a lamp heater is employed to heat the collection vessel. In some embodiments, a heat transfer fluid at elevated temperature may be contacted with the exterior surface of the collection vessel, to effect heating and/or cooling thereof. In some embodiments, the heating is conducted by infrared or other radiant energy being impinged on the collection vessel. In some embodiments, the collection vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The collection vessel may be configured to control pressure. The pressure of the collection vessel may be controlled in any suitable manner. In some embodiments, a gas inlet line is fluidly coupled to the collection vessel. The gas inlet line may be configured to supply a pressurizing gas from a pressurizing gas source to the collection vessel. Control of the pressurizing gas into the collection vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the collection vessel. The vacuum line may be configured to apply a vacuum to the collection vessel. In some embodiments, the pumping speed is controlled by butterfly valves. It will be appreciated that other mechanisms for controlling the pressure of the source vessel may be employed herein without departing from the scope of this disclosure.

At step 306, in some embodiments, a third condition is applied to the collection vessel, so as to produce a WCl₅ condensate or a WCl₆ condensate, and a second WOCl₄ vapor. In some embodiments, producing the WCl₅ condensate or the WCl₆ condensate, and the second WOCl₄ vapor results in separating the WCl₅ or the WCl₆ from the second portion of WOCl₄. In some embodiments, the third condition includes a third temperature of the collection vessel. In some embodiments, the third temperature of the collection vessel is a temperature in a range of 10° C. to 100° C., or any range or subrange therebetween. In some embodiments, the third temperature of the collection vessel is a temperature in a range of 20° C. to 100° C., 30° C. to 100° C., 40° C. to 100° C., 50° C. to 100° C., 60° C. to 100° C., 70° C. to 100° C., 80° C. to 100° C., 90° C. to 100° C., 10° C. to 90° C., 10° C. to 80° C., 10° C. to 70° C., 10° C. to 60° C., 10° C. to 50° C., 10° C. to 40° C., 10° C. to 30° C., or 10° C. to 20° C. In some embodiments, the third temperature of the collection vessel is a temperature sufficient to cause the WCl₅ vapor or the WCl₆ vapor to condense. In some embodiments, the third temperature of the collection vessel is a temperature sufficient to result in the second WOCl₄ vapor.

In some embodiments, the third condition includes a third pressure of the collection vessel. In some embodiments, the third pressure of the collection vessel is a pressure in a range of 0.01 Torr to 100 Torr, or any range or subrange therebetween. In some embodiments, the third pressure of the collection vessel is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 1 Torr, 0.01 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr. In some embodiments, the third pressure of the collection vessel is a pressure sufficient to cause the WCl₅ vapor or the WCl₆ vapor to condense. In some embodiments, the third pressure of the collection vessel is a pressure sufficient to result in the second WOCl₄ vapor.

In some embodiments, the third condition is applied to the collection vessel, so as to produce a WCl₅ condensate or a WCl₆ condensate, and a WOCl₄ vapor. In some embodiments, the third condition is a condition sufficient to condense the WCl₅ or the WCl₆, without condensing the WOCl₄ or at least to minimize the volume of WOCl₄ that is condensed, so as to separate the WCl₅ or the WCl₆ from the WOCl₄. In some embodiments, the third condition is a condition under which a greater volume of the WCl₅ or the WCl₆ condenses than the WOCl₄. In some embodiments, the WCl₅ condensate or the WCl₆ condensate comprises a greater amount (e.g., mole fraction, volume, or mass fraction) of the WCl₅ condensate or the WCl₆ condensate, than WOCl₄ condensate (if any). In some embodiments, the third condition is a condition under which a greater volume of WOCl₄ remains vaporized than WCl₅ or WCl₆. In some embodiments, the third condition is a condition under which the WOCl₄ vapor comprises the WOCl₄ which was dissolved in the crystal lattice of the WCl₅ or the WCl₆ (as well as, in some embodiments, isolated crystals of WOCl₄) and which was vaporized with the WCl₅ or the WCl₆ in the source vessel.

At step 308, in some embodiments, at least a portion of the second WOCl₄ vapor is removed from the collection vessel. The second WOCl₄ vapor may be removed via an outlet of the collection vessel. The outlet may be fluidly coupled to a gas discharge line, a vacuum line, or other similar line suitable for removing the second WOCl₄ vapor from the collection vessel.

FIG. 4 is a flowchart of a method 400 for validating a low impurity content of a tungsten precursor, according to some embodiments. As shown in FIG. 4, in some embodiments, the method 400 for validating a low impurity content of a tungsten precursor may comprise at least one of the following steps: a step 402 of measuring a WOCl₄ content of the precursor, so as to validate or not validate the low WOCl₄ content of the precursor; a step 404 of comparing to a reference value to validate or not validate the low WOCl₄; a step 406 of, when the low WOCl₄ content of the precursor is not validated, further removing WOCl₄ (e.g., by repeating at least one of the step 104 (e.g., including, without limitation, any one or more of the steps of FIG. 2), the step 106 (e.g., including, without limitation, any one or more of the steps of FIG. 3), or any combination thereof); or any combination thereof. In some embodiments, when the low WOCl₄ content is validated, the precursor is ready for use 408. In some embodiments, the method 400 relates to a method for validating the low WOCl₄ content of the tungsten precursor.

FIG. 5 is a flowchart of a method 500 for measuring a low impurity content of a tungsten precursor, according to some embodiments. As shown in FIG. 5, in some embodiments, the method 500 for measuring a low impurity content of a tungsten precursor may comprise at least one of the following steps: a step 502 of applying a fourth condition to the collection vessel containing the WCl₅ precursor or the WCl₆ precursor; a step 504 of measuring at least one property within the collection vessel; a step 506 of comparing the at least one property to a reference value. Although not shown, in some embodiments, the method 500 for measuring a low impurity content of the tungsten precursor further comprises a step of removing any vapor and/or gas from the collection vessel prior to performing the step 502. Although not shown, in some embodiments, the fourth condition is selected to stabilize the collection vessel at a reference temperature; an inlet gas flow to the collection vessel is stopped; a short vacuum pump removes inert gas from the vapor phase in the collection vessel; the collection vessel is isolated from the vacuum pump; and then the pressure in the collection vessel is monitored or measured over time. In some embodiments, the method 500 relates to a method for measuring the low WOCl₄ content of the tungsten precursor as described above.

At step 502, in some embodiments, the fourth condition is applied to the collection vessel containing the WCl₅ precursor or the WCl₆ precursor. In some embodiments, the fourth condition includes a fourth temperature of the collection vessel. In some embodiments, the fourth temperature of the collection vessel is a temperature in a range of 60° C. to 170° C., or any range or subrange between 60° C. to 170° C. In some embodiments, the fourth temperature of collection vessel is a temperature in a range of 60° C. to 160° C., 60° C. to 150° C., 60° C. to 140° C., 60° C. to 130° C., 60° C. to 120° C., 60° C. to 110° C., 60° C. to 100° C., 60° C. to 90° C., 60° C. to 80° C., 60° C. to 70° C., 70° C. to 170° C., 80° C. to 170° C., 90° C. to 170° C., 100° C. to 170° C., 110° C. to 170° C., 120° C. to 170° C., 130° C. to 170° C., 140° C. to 170° C., 150° C. to 170° C., 160° C. to 170° C., 100° C. to 160° C., 120° C. to 160° C., 140° C. to 160° C., 120° C. to 150° C., 120° C. to 140° C., or 110° C. to 150° C.

In some embodiments, the fourth condition includes a fourth pressure of the collection vessel. In some embodiments, the fourth pressure of the collection vessel is a pressure in a range of 0.01 Torr to 100 Torr, or any range or subrange therebetween. In some embodiments, the fourth pressure of the collection vessel is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 1 Torr, 0.01 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr.

In some embodiments, the fourth condition is a condition under which a total pressure of the collection vessel is within 10% of the true vapor pressure of the WCl₅ or the WCl₆. In some embodiments, the fourth condition is a condition under which a total pressure of the collection vessel is below a true vapor pressure of the WOCl₄.

At step 504, in some embodiments, at least one property is measured within the collection vessel. In some embodiments, the at least one property is at least one of the total pressure within the collection vessel, the rate of change of total pressure within the collection vessel, or any combination thereof is measured. In some embodiments, the rate of change of total pressure is a rate of increase in pressure per unit time. For example, in some embodiments, the rate of change of total pressure is a rate of increase in pressure in Torr per minute. In some embodiments, the rate of change of total pressure is a rate of increase in pressure in millitorr per minute. In some embodiments, the rate of change of total pressure within the collection vessel is measured for a duration between 30 seconds and 24 hours. It will be appreciated that the rate of change of total pressure may be in any suitable pressure units and time units. It will further be appreciated that the duration over which the rate of change of total pressure within the collection vessel is measured may vary depending on the composition of the precursor (e.g., level of impurities) and the chosen temperature for the fourth condition.

At step 506, in some embodiments, the total pressure within the collection vessel is compared to a reference value. In some embodiments, when the total pressure is within 0.01% to 20% (inclusive), or any range or subrange therebetween, of the reference value, the low WOCl₄ content of the precursor is validated. In some embodiments, when the total pressure is not within 0.01% to 20% of the reference value, the low WOCl₄ content of the precursor is not validated. In some embodiments, the reference value is the true vapor pressure of the WCl₅ at conditions (e.g., a select temperature). In some embodiments, the low WOCl₄ content is validated if the measured total pressure is within 1% to 15%, 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, 1% to 2%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, 14% to 15%, 2% to 10%, 3% to 10%, 4% to 10%, 5% to 10%, 6% to 10%, 7% to 10%, 8% to 10%, or 9% to 10% of the true vapor pressure of the WCl₅ at conditions.

At step 506, in some embodiments, the rate of change of total pressure within the collection vessel is compared to a reference value. In some embodiments, when the rate of change of total pressure is greater than the reference value, the low WOCl₄ content of the precursor is not validated. In some embodiments, when the rate of change of total pressure is equal to or less than the reference value, the low WOCl₄ content of the precursor is validated. For example, in some embodiments, when the rate of change of total pressure is 20% or less, 15% or less, 10% or less, 5% or less, 4% or less, 3% or less, 2% or less, or 1% or less per unit minute, the low WOCl₄ content of the precursor is validated. In some embodiments, the reference value is 50 mT per min or less. For example, in some embodiments, the reference value is 45 mT per min or less, 40 mT per min or less, 35 mT per min or less, 30 mT per min or less, 25 mT per min or less, 20 mT per min or less, 15 mT per min or less, 10 mT per min or less, or 5 mT per min or less. It can be appreciated that for lower temperatures of the fourth condition, the limiting value of pressure rise rate will be lower.

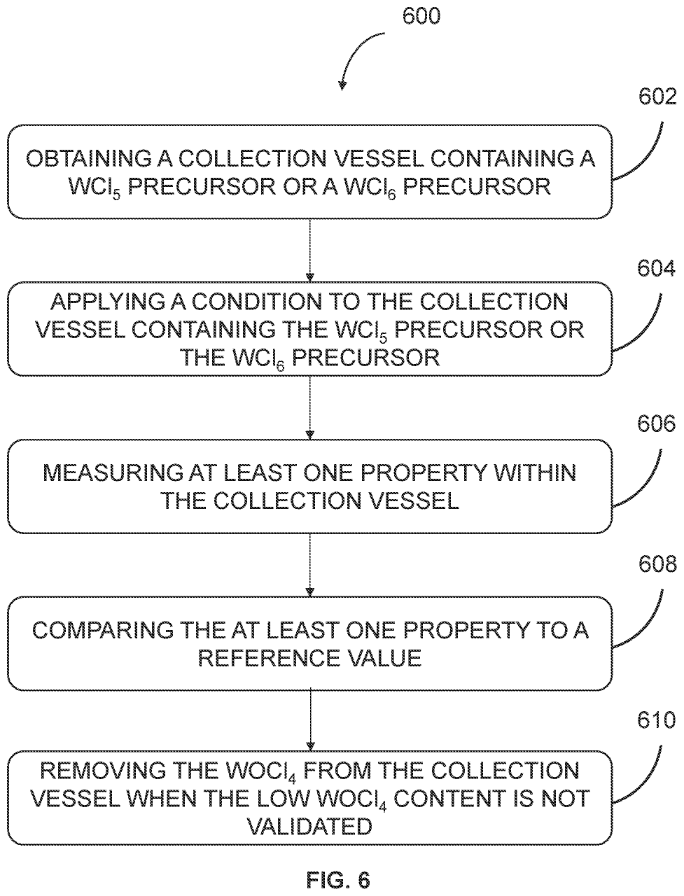

FIG. 6 is a flowchart of a method 600 for validating a low impurity content, according to some embodiments. As shown in FIG. 6, in some embodiments, the method 600 for validating a low impurity content comprises at least one of the following steps: a step 602 of obtaining a collection vessel containing a WCl₅ precursor or a WCl₆ precursor; a step 604 of applying a condition to the collection vessel containing the WCl₅ precursor or the WCl₆ precursor; a step 606 of measuring at least one property within the collection vessel (e.g., at least one of a rate of change of total pressure within the collection vessel, a total pressure within the collection vessel, or any combination thereof); a step 608 comparing the at least one property to a reference value; a step 610 of removing the WOCl₄ from the collection vessel when the low WOCl₄ content is not validated; or any combination thereof. Although not shown, in some embodiments, the condition is selected to stabilize the collection vessel at a reference temperature; an inlet gas flow to the collection vessel is stopped; a short vacuum pump removes inert gas from the vapor phase in the collection vessel; the collection vessel is isolated from the vacuum pump; and then the pressure in the collection vessel is monitored or measured over time.

Some embodiments relate to a tungsten precursor having sufficiently low impurity levels such that, when supplied to a tool used in semiconductor fabrication or other similar processes, the tungsten precursor, upon being vaporized, is supplied to the tool at a controllable constant flow rate, without appreciable spikes or variations in flow rate. In some embodiments, a precursor vessel is provided. The precursor vessel may comprise a tungsten precursor, such as, for example and without limitation, a WCl₅ precursor or a WCl₆ precursor, having sufficiently low levels of impurities. The impurities may include, for example and without limitation, at least one of WOCl₄, WCl₄, or any combination thereof.

In some embodiments, the WCl₅ precursor, when contained in the precursor vessel, has, when the precursor vessel is maintained at a temperature of 70° C. to 240° C. (or any range or subrange therebetween), a vapor pressure of less than 1.3 times a calculated vapor pressure of WCl₅ determined according to the formula:

$$\\ Log P ( Torr ) = 11.119 + \frac{- 4634}{T ( K )} .$$

In some embodiments, the WCl₅ precursor, when contained in the precursor vessel, has, when the precursor vessel is maintained at a temperature of 70° C. to 240° C. (or any range or subrange therebetween), a vapor pressure of less than 1.1 times a calculated vapor pressure of WCl₅ determined according to the formula:

$$\\ Log P ( Torr ) = 11.119 + \frac{- 4634}{T ( K )}$$

In some embodiments, the WCl₆ precursor, when contained in the precursor vessel, has, when the precursor vessel is maintained at a temperature of 70° C. to 240° C. (or any range or subrange therebetween), a vapor pressure of less than 1.3 times a calculated vapor pressure of WCl₆ determined according to the formula:

$$\\ Log P ( Torr ) = 11.429 + \frac{- 4894}{T ( K )}$$

In some embodiments, the WCl₆ precursor, when contained in the precursor vessel, has, when the precursor vessel is maintained at a temperature of 70° C. to 240° C. (or any range or subrange therebetween), a vapor pressure of less than 1.1 times a calculated vapor pressure of WCl₆ determined according to the formula:

$$\\ Log P ( Torr ) = 11.429 + \frac{- 4894}{T ( K )}$$

The WCl₆ or the WCl₆ may maintain the vapor pressure for an indefinite duration. In some embodiments, the WCl₆ or the WCl₆ maintains the vapor pressure for duration of up to 72 hours. In some embodiments, the WCl₆ or the WCl₆ maintains the vapor pressure for a duration of 5 minutes to 72 hours, or any range or subrange therebetween.

Aspects

Various Aspects are described below. It is to be understood that any one or more of the features recited in the following Aspect(s) can be combined with any one or more other Aspect(s).

Aspect 1. A method comprising:
a) obtaining a source vessel containing WCl₄, WOCl₄, and one of WCl₆ or WCl₆;
b) separating the WCl₆ or the WCl₆ from a first portion of the WOCl₄, wherein the separating comprises:
   applying a first condition to the source vessel, so as to produce a first WOCl₄ vapor;
   removing at least a portion of the first WOCl₄ vapor from the source vessel;
c) separating the WCl₆ or the WCl₆ from a second portion of the WOCl₄, wherein the separating comprises:
   applying a second condition to the source vessel, so as to produce a WCl₆ vapor comprising WOCl₄ or a WCl₆ vapor comprising WOCl₄;
   flowing the WCl₅ vapor or the WCl₆ vapor to a collection vessel;
   applying a third condition to the collection vessel, so as to produce a WCl₅ condensate or a WCl₆ condensate, and a second WOCl₄ vapor;
   removing at least a portion of the second WOCl₄ vapor from the collection vessel; and
d) recovering a precursor in a collection vessel.

Aspect 2. The method of Aspect 1, wherein the first condition is a condition under which a total pressure of the source vessel is below a true vapor pressure of WOCl₄ for a given first temperature.

Aspect 3. The method according to any one of Aspects 1-2, wherein the first condition is a condition under which a total pressure of the source vessel is above a true vapor pressure of WCl₅ or WCl₆ for a given first temperature.

Aspect 4. The method according to any one of Aspects 1-3, wherein, when applying the first condition, the first WOCl₄ vapor comprises a greater volume of WOCl₄ than WCl₅ or WCl₆.

Aspect 5. The method according to any one of Aspects 1-4, wherein the second condition is a condition under which a total pressure of the source vessel is below a true vapor pressure of the WCl₅ or the WCl₆ for a given second temperature.

Aspect 6. The method of Aspect 4, wherein the second condition is a condition under which a total pressure of the source vessel is above a true vapor pressure of the WCl₄ for a given second temperature.

Aspect 7. The method according to any one of Aspects 1-6, wherein, when applying the second condition, the WCl₅ vapor comprises a greater volume of the WCl₅ than the WCl₄.

Aspect 8. The method according to any one of Aspects 1-7, wherein, when applying the second condition, the WCl₆ vapor comprises a greater volume of the WCl₆ than the WCl₄.

Aspect 9. The method according to any one of Aspects 1-8, wherein, when applying the second condition, the WCl₅ vapor comprises a greater volume of the WOCl₄ than the WCl₄.

Aspect 10. The method according to any one of Aspects 1-9, wherein, when applying the second condition, the WCl₆ vapor comprises a greater volume of the WOCl₄ than the WCl₄.

Aspect 11. The method according to any one of Aspects 1-10, wherein the third condition is a condition under which a greater volume of the WCl₅ condenses than the WOCl₄.

Aspect 12. The method according to any one of Aspects 1-11, wherein the third condition is a condition under which a greater volume of the WCl₆ condenses than the WOCl₄.

Aspect 13. The method according to any one of Aspects 1-12, wherein, when applying the third condition, the WCl₅ condensate comprises a greater mole fraction of WCl₅ than WOCl₄.

Aspect 14. The method according to any one of Aspects 1-13, wherein, when applying the third condition, the WCl₆ condensate comprises a greater mole fraction of WCl₆ than WOCl₄.

Aspect 15. The method according to any one of Aspects 1-14, further comprising:
e) validating a low WOCl₄ content of the precursor present in the collection vessel. Aspect 16. The method of Aspect 15, wherein the validating step e) comprises:
   e1) measuring a WOCl₄ content of the precursor, so as to validate or not validate the low WOCl₄ content of the precursor;
   e2) when the low WOCl₄ content of the precursor is not validated, repeating at least one of step b), step c), or any combination thereof, so as to remove the WOCl₄.

Aspect 17. The method of Aspect 16, wherein the measuring step e1) comprises:
applying a fourth condition to the collection vessel containing the precursor;
measuring at least one property within the collection vessel; and
comparing the measured property to a reference value.

Aspect 18. The method of Aspect 17, wherein the at least one property is a total pressure within the collection vessel,
wherein, when the total pressure is within 1% to 10% of a true vapor pressure of the WCl₅, the low WOCl₄ content is validated;
wherein, when the total pressure is not within 1% to 10% of the true vapor pressure of the WCl₅, the low WOCl₄ content is not validated.

Aspect 19. The method of Aspect 17, wherein the at least one property is a total pressure within the collection vessel,
wherein, when the total pressure is within 1% to 10% of a true vapor pressure of the WCl₆, the low WOCl₄ content is validated;
wherein, when the total pressure is not within 1% to 10% of the true vapor pressure of the WCl₆, the low WOCl₄ content is not validated.

Aspect 20. The method of Aspect 17, wherein the at least one property is a rate of change of total pressure within the collection vessel,
wherein, when the rate of change of total pressure is greater than the reference value, the low WOCl₄ content of the precursor is not validated;
wherein when the rate of change of total pressure is equal to or less than the reference value, the low WOCl₄ content of the precursor is validated;
wherein the reference value is a 5% change in total pressure per minute.

Aspect 21. The method of Aspect 17, wherein the fourth condition is a condition under which a total pressure of the collection vessel is below a true vapor pressure of the WOCl₄.

Aspect 22. A method for validating a low impurity content, the method comprising:
obtaining a collection vessel containing a WCl₅ precursor or a WCl₆ precursor;
applying a condition to the collection vessel containing the WCl₅ precursor or the WCl₆ precursor;
measuring at least one property within the collection vessel;
comparing the at least one property to a reference value;
removing the WOCl₄ from the collection vessel when the low WOCl₄ content is not validated.

Aspect 23. The method of Aspect 22, wherein the at least one property is a total pressure within the collection vessel,
wherein, when the total pressure is within 10% of a true vapor pressure of the WCl₅, the low WOCl₄ content is validated;
wherein, when the total pressure is not within 10% of the true vapor pressure of the WCl₅, the low WOCl₄ content is not validated.

Aspect 24. The method of Aspect 22, wherein the at least one property is a total pressure within the collection vessel,
wherein, when the total pressure is within 1% of a true vapor pressure of the WCl₆, the low WOCl₄ content is validated;
wherein, when the total pressure is not within 1% of the true vapor pressure of the WCl₆, the low WOCl₄ content is not validated.

Aspect 25. The method of Aspect 22, wherein the at least one property is a rate of change of total pressure within the collection vessel,
wherein, when the rate of change of total pressure is greater than the reference value, the low WOCl₄ content of the precursor is not validated;
wherein when the second rate of change of total pressure is equal to or less than the reference value, the low WOCl₄ content of the precursor is validated;
wherein the reference value is a 5% change in total pressure per minute.

Aspect 26. A precursor vessel comprising:
a precursor comprising WCl₅,
   wherein the WCl₅ having, when the precursor vessel is maintained at a temperature of 70° C. (343.15 K) to 240° C. (513.15 K), a vapor pressure of less than 1.1 times a true vapor pressure of WCl₅.

Aspect 27. The precursor vessel of Aspect 26, wherein the true vapor pressure of WCl₅ is calculated according to the formula:

$$\\ Log P ( Torr ) = 11.119 + \frac{- 4634}{T ( K )} .$$

Aspect 28. The precursor vessel of Aspect 26, wherein the WCl₅ maintains the vapor pressure within the precursor vessel for a duration up to 72 hours.

Aspect 29. A precursor vessel comprising:
a precursor comprising WCl₆,
   wherein the WCl₆ having, when the precursor vessel is maintained at a temperature of 70° C. (343.15 K) to 240° C. (513.15 K), a vapor pressure of less than 1.1 times a true vapor pressure of WCl₆.

Aspect 30. The precursor vessel of Aspect 29, wherein the true vapor pressure of WCl₆ is calculated according to the formula:

$$\\ Log P ( Torr ) = 11.429 + \frac{- 4894}{T ( K )} .$$

Aspect 31. The precursor vessel of Aspect 29, wherein the WCl₆ maintains the vapor pressure within the precursor vessel for a duration up to 72 hours.

### Example 1

Material was loaded into an ampoule and sealed with valve under inert conditions. The ampoule was installed on a system that controls temperature, measures absolute pressure, and allows for pumping. The ampoule was heated to a temperature and stabilized for 30 minutes. The ampoule was pumped for a pre-determined pumping time. Then the pressure measurement manifold was isolated from the pump and the pressure was measured as a function of time for 5 minutes. The process may be repeated as many times as desired to achieve purity level desired.

### Example 2

Material was loaded into ampoule and sealed with valve under inert conditions. The ampoule was installed on a system that controls temperature, measures absolute pressure, and allows for pumping. The ampoule was pumped to remove inert gas and then heated to a desired temperature and stabilized for 30 minutes. The ampoule was pumped for 10 seconds. The ampoule was allowed to thermally re-equilibrate for 5 minutes while pumping the pressure measurement manifold. Then the pressure measurement manifold was isolated from the pump and opened to the ampoule for a pressure measurement. The pressure was measured as a function of time for 5 minutes. The material was validated because the initial pressure measurement was within 10% of the true vapor pressure of WCl₅. Material may also be validated if the pressure rise rate is less than about 3%/minute.

### Example 3

Material was loaded into ampoule and sealed with valve under inert conditions. The ampoule was installed on a system that controls temperature, measures absolute pressure, and allows for pumping. The ampoule was pumped to remove inert gas and then heated to a desired temperature and stabilized for 30 minutes. The ampoule was pumped for 10 seconds. The ampoule was allowed to thermally re-equilibrate for 5 minutes while pumping the pressure measurement manifold. Then the pressure measurement manifold was isolated from the pump and opened to the ampoule for a pressure measurement. The pressure was measured as a function of time for 5 minutes. The material was validated because the pressure rise rate was less than 3%/minute.

### Example 4

An equation representing vapor pressures measured for tungsten chloride and oxychloride materials is presented below.

$$\\ Log P ( Torr ) = A + \frac{B}{T ( K )}$$

| Material | A | B |
|---|---|---|
| WCl₆ | 11.429 | −4894 |
| WCl₅ | 11.119 | −4634 |
| WCl₅ + WCl₆ | 11.605 | −4759 |
| WOCl₄ | 12.094 | −4584 |

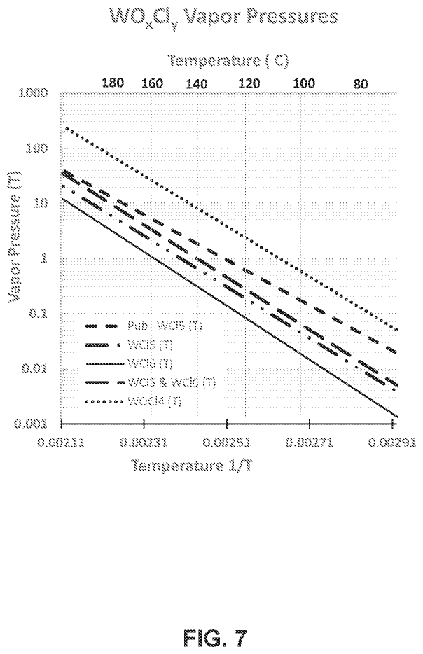

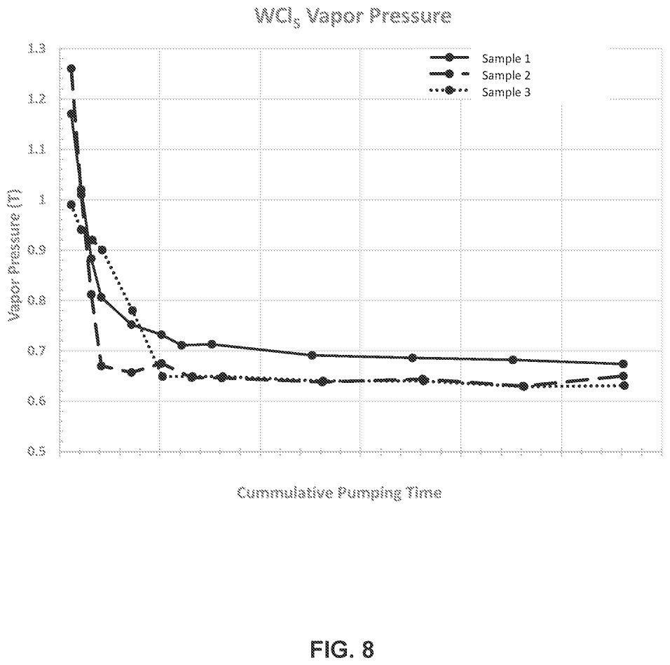

FIG. 7 is a graphical view of a vapor pressure curve, according to some embodiments. FIG. 8 is a graphical view of vapor pressure versus pumping time, according to some embodiments.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
a) obtaining a source vessel containing WOCl₄ and one of WCl₅ or WCl₆;
b) separating the WCl₅ or the WCl₆ from a first portion of the WOCl₄, wherein the separating comprises:
applying a first condition to the source vessel, so as to produce a first WOCl₄ vapor;
removing at least a portion of the first WOCl₄ vapor from the source vessel;
c) separating the WCl₅ or the WCl₆ from a second portion of the WOCl₄, wherein the separating comprises:
applying a second condition to the source vessel, so as to produce a WCl₅ vapor comprising WOCl₄ or a WCl₆ vapor comprising WOCl₄;
flowing the WCl₅ vapor or the WCl₆ vapor to a collection vessel;
applying a third condition to the collection vessel, so as to produce a WCl₅ condensate or a WCl₆ condensate, and a second WOCl₄ vapor;
removing at least a portion of the second WOCl₄ vapor from the collection vessel; and
d) recovering a precursor in a collection vessel.

2. The method of claim 1 wherein the source vessel further contains WCl₄.

3. The method of claim 1, wherein the first condition is a condition under which a total pressure of the source vessel is below a true vapor pressure of WOCl₄ for a given first temperature.

4. The method of claim 3, wherein the first condition is a condition under which a total pressure of the source vessel is above a true vapor pressure of WCl₅ or WCl₆ for a given first temperature.

5. The method of claim 1, wherein, when applying the first condition, the first WOCl₄ vapor comprises a greater volume of WOCl₄ than WCl₅ or WCl₆.

6. The method of claim 1, wherein the second condition is a condition under which a total pressure of the source vessel is below a true vapor pressure of the WCl₅ or the WCl₆ for a given second temperature.

7. The method of claim 2, wherein the second condition is a condition under which a total pressure of the source vessel is above a true vapor pressure of the WCl₄ for a given second temperature.

8. The method of claim 2, wherein, when applying the second condition, the WCl₅ vapor comprises a greater volume of the WCl₅ than the WCl₄.

9. The method of claim 2, wherein, when applying the second condition, the WCl₆ vapor comprises a greater volume of the WCl₆ than the WCl₄.

10. The method of claim 2, wherein, when applying the second condition, the WCl₅ vapor comprises a greater volume of the WOCl₄ than the WCl₄.

11. The method of claim 2, wherein, when applying the second condition, the WCl₆ vapor comprises a greater volume of the WOCl₄ than the WCl₄.

12. The method of claim 1, wherein the third condition is a condition under which a greater volume of the WCl₅ condenses than the WOCl₄.

13. The method of claim 1, wherein the third condition is a condition under which a greater volume of the WCl₆ condenses than the WOCl₄.

14. The method of claim 1, further comprising:
e) validating a low WOCl₄ content of the precursor present in the collection vessel. wherein the validating step e) comprises:
e1) measuring a WOCl₄ content of the precursor, so as to validate or not validate the low WOCl₄ content of the precursor;
e2) when the low WOCl₄ content of the precursor is not validated, repeating at least one of step b), step c), or any combination thereof, so as to remove the WOCl₄.

15. The method of claim 14, wherein the measuring step e1) comprises:
applying a fourth condition to the collection vessel containing the precursor;
measuring at least one property within the collection vessel; and
comparing the measured property to a reference value.

16. The method of claim 15, wherein the at least one property is a total pressure within the collection vessel,
wherein, when the total pressure is within 1% to 10% of a true vapor pressure of the WCl₅, the low WOCl₄ content is validated;
wherein, when the total pressure is not within 1% to 10% of the true vapor pressure of the WCl₅, the low WOCl₄ content is not validated.

17. A method for validating a low impurity content, the method comprising:
obtaining a collection vessel containing a WCl₅ precursor or a WCl₆ precursor;
applying a condition to the collection vessel containing the WCl₅ precursor or the WCl₆ precursor;
measuring at least one property within the collection vessel;
comparing the at least one property to a reference value;
removing the WOCl₄ from the collection vessel when the low WOCl₄ content is not validated.

18. The method of claim 17, wherein the at least one property is a total pressure within the collection vessel,
wherein, when the total pressure is within 10% of a true vapor pressure of the WCl₅, the low WOCl₄ content is validated;
wherein, when the total pressure is not within 10% of the true vapor pressure of the WCl₅, the low WOCl₄ content is not validated.

19. A precursor vessel comprising:
a precursor comprising WCl₅,
wherein the WCl₅ having, when the precursor vessel is maintained at a temperature of 70° C. (343.15 K) to 240° C. (513.15 K), a vapor pressure of less than 1.3 times a true vapor pressure of WCl₅.

20. The precursor vessel of claim 28, wherein the true vapor pressure of WCl₅ is calculated according to the formula:
$$\\ Log P ( Torr ) = 11.119 + \frac{- 4634}{T ( K )} .$$
